(19) United States
(12) Patent Application Publication
(10) Pub. No.: US 2016/0268368 A1
(43) Pub. Date: Sep. 15, 2016

(54) SEMICONDUCTOR DEVICE AND METHOD FOR MANUFACTURING SEMICONDUCTOR DEVICE

(71) Applicant: KABUSHIKI KAISHA TOSHIBA, Tokyo (JP)

(72) Inventors: Shizue Matsuda, Kanazawa Ishikawa (JP); Noboru Yokoyama, Kanazawa Ishikawa (JP)

(21) Appl. No.: 14/826,656

(22) Filed: Aug. 14, 2015

(30) Foreign Application Priority Data
Mar. 13, 2015 (JP) 2015-050766

(51) Int. Cl. H01L 29/06; H01L 29/32; H01L 29/10; H01L 29/78; H01L 29/66

(52) U.S. Cl. CPC H01L 29/0634; H01L 29/7813; H01L 29/7811; H01L 29/66734; H01L 29/0696; H01L 29/1095; H01L 29/32

(57) ABSTRACT

According to one embodiment, a semiconductor device includes a first semiconductor region of a first conductivity type, a second semiconductor region of a second conductivity type, a third semiconductor region of the second conductivity type, a fourth semiconductor region of the first conductivity type, a gate electrode, and a gate insulating layer. The first semiconductor region includes first portions and second portions. A length in a second direction of the second portion is longer than a length in the second direction of the first portion. The plurality of first portions and the plurality of second portions are provided alternately in a third direction. Part of the third semiconductor region is located between the second portions. An impurity concentration of the second conductivity type of the third semiconductor region is lower than an impurity concentration of the second conductivity type of the second semiconductor region.

### CROSS-REFERENCE TO RELATED APPLICATIONS

This application is based upon and claims the benefit of priority from Japanese Patent Application No. 2015-050766, filed on Mar. 13, 2015; the entire contents of which are incorporated herein by reference.

### FIELD

Embodiments described herein relate generally to a semiconductor device and a method for manufacturing semiconductor device.

### BACKGROUND

Semiconductor devices such as MOSFET (metal oxide semiconductor field effect transistor) may have a super-junction structure in order to improve its breakdown voltage. The super-junction structure is formed by e.g. forming a plurality of openings in an n-type semiconductor layer and forming a p-type semiconductor layer in these openings. In the case of MOSFET, a base region, a source region, and a gate electrode are formed after forming the super-junction structure.

Improvement in productivity is desired in semiconductor devices having a super-junction structure.

### BRIEF DESCRIPTION OF THE DRAWINGS

FIG. 1 is a perspective sectional view showing part of the semiconductor device according to the first embodiment;

FIG. 2 is a sectional view enlarging part of FIG. 1;

FIGS. 3A to 8B are process sectional views showing a process for manufacturing the semiconductor device 100 according to the first embodiment;

FIG. 9 is a perspective sectional view showing part of the semiconductor device 200 according to the second embodiment; and

FIG. 10 is a process sectional view showing a process for manufacturing the semiconductor device.

### DETAILED DESCRIPTION

According to one embodiment, a semiconductor device includes a first semiconductor region of a first conductivity type, a second semiconductor region of a second conductivity type, a third semiconductor region of the second conductivity type, a fourth semiconductor region of the first conductivity type, a gate electrode, and a gate insulating layer. The first semiconductor region includes a plurality of first portions and a plurality of second portions. Each of the first portions extends in a first direction. Each of the second portions extends in the first direction. A length in a second direction of the second portion is longer than a length in the second direction of the first portion. The second direction is orthogonal to the first direction. The plurality of first portions and the plurality of second portions are provided alternately in a third direction orthogonal to the first direction and the second direction. The second semiconductor region is provided on the first semiconductor region. The third semiconductor region is provided on the second semiconductor region. Part of the third semiconductor region is located between the second portions. An impurity concentration of the second conductivity type of the third semiconductor region is lower than an impurity concentration of the second conductivity type of the second semiconductor region. The fourth semiconductor region is selectively provided on the third semiconductor region. The gate electrode is provided on the second portion. The gate insulating layer is provided between the gate electrode and each of the second portion, the second semiconductor region, the third semiconductor region, and the fourth semiconductor region.

Embodiments of the invention will now be described with reference to the drawings.

The drawings are schematic or conceptual. The relationship between the thickness and the width of each portion, and the size ratio between the portions, for instance, are not necessarily identical to those in reality. Furthermore, the same portion may be shown with different dimensions or ratios depending on the figures.

In this specification and the drawings, components similar to those described previously are labeled with like reference numerals, and the detailed description thereof is omitted appropriately.

An XYZ orthogonal coordinate system is used in the description of the embodiments. Two directions parallel to the major surface of the semiconductor layer S and orthogonal to each other are referred to as X-direction (third direction) and Y-direction (first direction). The direction orthogonal to both the X-direction and the Y-direction is referred to as Z-direction (second direction).

In the following description, the notations of n⁺, n⁻ and p⁺, p, p⁻ represent relative magnitude of impurity concentration in the respective conductivity types. More specifically, the symbol n⁺ represents relatively higher n-type impurity concentration than n⁻. The symbol p⁺ represents relatively higher p-type impurity concentration than p, and p⁻ represents relatively lower p-type impurity concentration than p.

The embodiments described below may be practiced by reversing the p-type and the n-type of each semiconductor region.

### First Embodiment

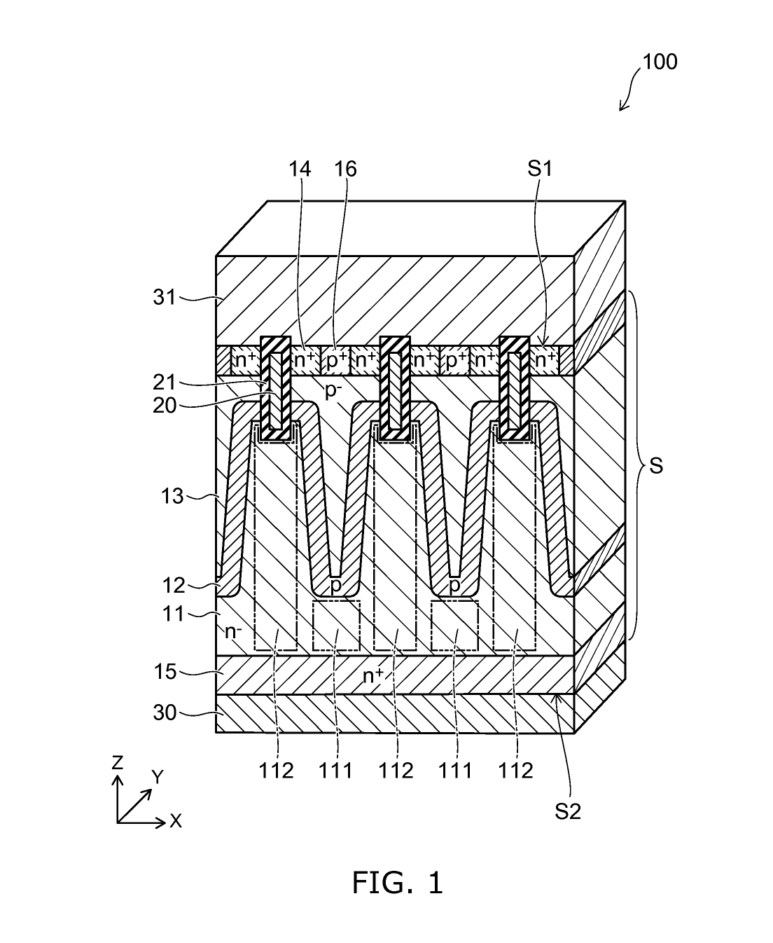

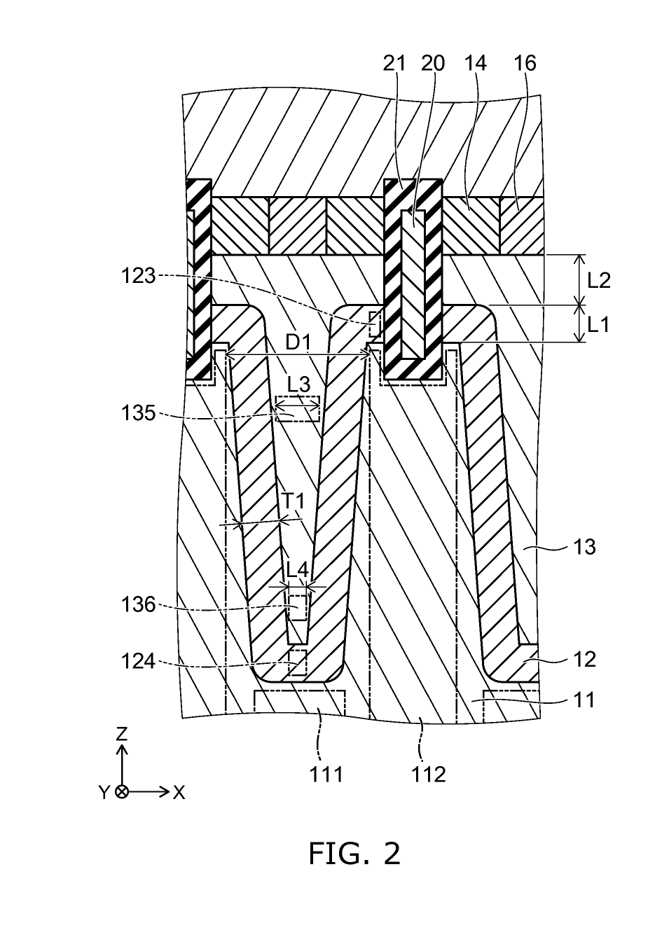

A semiconductor device 100 according to a first embodiment is described with reference to FIGS. 1 and 2.

FIG. 1 is a perspective sectional view showing part of the semiconductor device 100 according to the first embodiment.

FIG. 2 is a sectional view enlarging part of FIG. 1.

The semiconductor device 100 according to the first embodiment is e.g. a MOSFET.

The semiconductor device 100 according to the first embodiment includes an n⁺-type drain region 15, an n⁻-type semiconductor region 11 (first semiconductor region of a first conductivity type), a p-type semiconductor region 12 (second semiconductor region of a second conductivity type), a p⁻-type semiconductor region 13 (third semiconductor region), an n⁺-type source region 14 (fourth semiconductor region), a p⁺-type contact region 16, a gate electrode 20, a gate insulating layer 21, a drain electrode 30, and a source electrode 31.

The semiconductor layer S has a front surface S1 and a back surface S2. The source electrode 31 is provided on the front surface S1 side of the semiconductor layer S. The drain electrode 30 is provided on the back surface S2 side of the semiconductor layer S.

The n⁺-type drain region 15 is provided on the back surface S2 side in the semiconductor layer S. The n⁺-type drain region 15 is electrically connected to the drain electrode 30. The n⁻-type semiconductor region 11 is provided on the n⁺-type drain region 15.

The n⁻-type semiconductor region 11 includes a first portion 111 and a second portion 112. The first portion 111 and the second portion 112 are provided in a plurality in the X-direction. Each of the first portions 111 and each of the second portions 112 extend in the Y-direction. The Z-direction length of the second portion 112 is longer than the Z-direction length of the first portion 111. The first portions 111 and the second portions 112 are provided alternately in the X-direction.

The p-type semiconductor region 12 is provided on the n⁻-type semiconductor region 11. The p-type semiconductor region 12 is provided in a plurality in e.g. the X-direction. Each p-type semiconductor region 12 extends in the Y-direction. Part of the p-type semiconductor region 12 is provided between the gate electrodes 20 in the X-direction. Another part of the p-type semiconductor region 12 is provided between the second portions 112 in the X-direction.

The portion of the p-type semiconductor region 12 overlapping the second portions 112 in the X-direction is provided along the Z-direction, or along a direction being perpendicular to the Y-direction and inclined with respect to the Z-direction. The inclination of part of this portion with respect to the Z-direction may be different from the inclination of another part of this portion with respect to the Z-direction.

The interface between the first portion 111 and the p-type semiconductor region 12 lies along the X-direction. The interface between the second portion 112 and the p-type semiconductor region 12, for instance, lies along the Z-direction or is inclined with respect to the Z-direction. The inclination of the interface between part of the second portion 112 and the p-type semiconductor region 12 with respect to the Z-direction may be different from the inclination of the interface between another part of the second portion 112 and the p-type semiconductor region 12 with respect to the Z-direction.

The p⁻-type semiconductor region 13 is provided on the p-type semiconductor region 12. Part of the p⁻-type semiconductor region 13 overlaps the first portion 111 via the p-type semiconductor region 12 in the Z-direction. Another part of the p⁻-type semiconductor region 13 overlaps e.g. the second portion 112 via the p-type semiconductor region 12 in the Z-direction.

Part of the p⁻-type semiconductor region 13 is provided between the second portions 112 in the X-direction. Another part of the p⁻-type semiconductor region 13 is provided between the gate electrodes 20 in the X-direction. The p⁻-type semiconductor region 13 is provided in a plurality in e.g. the X-direction. Each p⁻-type semiconductor region 13 extends in the Y-direction.

Part of the second portion 112, part of the p-type semiconductor region 12, and part of the p⁻-type semiconductor region 13 form a super-junction structure.

The n⁺-type source region 14 is selectively provided on the p⁻-type semiconductor region 13. The n⁺-type source region 14 is electrically connected to the source electrode 31 provided on the front surface S1. At least part of the n⁺-type source region 14 overlaps the second portion 112 via the p-type semiconductor region 12 and the p⁻-type semiconductor region 13 in e.g. the Z-direction.

The p⁺-type contact region 16 may be further provided on the p⁻-type semiconductor region 13. The p⁺-type contact region 16 is provided between the n⁺-type source regions 14 in the X-direction.

The impurity concentration of the n⁺-type drain region 15 is e.g. 1×10¹⁸ atoms/cm³ or more.

The impurity concentration of the n⁻-type semiconductor region 11 is e.g. 1×10¹⁵ atoms/cm³ or more and 5×10¹⁶ atoms/cm³ or less.

The impurity concentration of the p-type semiconductor region 12 is e.g. 1×10¹⁶ atoms/cm³ or more and 1×10¹⁷ atoms/cm³ or less.

The impurity concentration of the p⁻-type semiconductor region 13 is e.g. 1×10¹⁶ atoms/cm³ or less.

The impurity concentration of the n⁺-type source region 14 is e.g. 1×10¹⁹ atoms/cm³ or more.

The impurity concentration of the p⁺-type contact region 16 is e.g. 1×10¹⁹ atoms/cm³ or more.

The gate electrode 20 is provided on the second portion 112 of the n⁻-type semiconductor region 11. The gate electrode 20 is provided in a plurality in e.g. the X-direction. Each gate electrode 20 extends in the Y-direction.

The gate insulating layer 21 is provided between the gate electrode 20 and the n⁻-type semiconductor region 11, the p-type semiconductor region 12, the p⁻-type semiconductor region 13, and the n⁺-type source region 14.

The source electrode 31 is provided on the front surface S1. The source electrode 31 is electrically connected to the n⁺-type source region 14 and the p⁺-type contact region 16. An insulating layer is provided between the source electrode 31 and the gate electrode 20. The source electrode 31 is electrically isolated from the gate electrode 20.

Part of the gate electrode 20 overlaps the second portion 112 via the gate insulating layer 21 in the X-direction.

The drain electrode 30 is applied with a positive voltage relative to the source electrode 31. In this state, the gate electrode 20 is applied with a voltage higher than or equal to a threshold. This turns on the MOSFET. At this time, a channel (inversion layer) is formed in the region of the p-type semiconductor region 12 and the p⁻-type semiconductor region 13 near the gate insulating layer 21.

In the off-state of the MOSFET, when the drain electrode 30 is applied with a positive potential relative to the potential of the source electrode 31, a depletion layer spreads in the second portion 112 and the p-type semiconductor region 12 from the p-n junction interface between the second portion 112 and the p-type semiconductor region 12. The second portion 112 and the p-type semiconductor region 12 are depleted vertically with respect to the junction interface between the second portion 112 and the p-type semiconductor region 12. This suppresses electric field concentration in the direction parallel to the junction interface between the second portion 112 and the p-type semiconductor region 12. Thus, a high breakdown voltage is achieved.

Part of the p-type semiconductor region 12 and part of the p⁻-type semiconductor region 13, for instance, are provided between the n⁺-type source region 14 and the second portion 112. Part of the p-type semiconductor region 12 may be provided in the entirety between the n⁺-type source region 14 and the second portion 112.

As shown in FIG. 2, the Z-direction length of the p-type semiconductor region 12 provided between the n⁺-type source region 14 and the second portion 112 is denoted by L1. The Z-direction length of the p⁻-type semiconductor region 13 provided between the n⁺-type source region 14 and the second portion 112 is denoted by L2. Preferably, the relation 0<L2/L1≦20 is satisfied. The lengths L1 and L2 can be confirmed by measuring the distribution of p-type impurity concentration between the second portion 112 and the n⁺-type source region 14. For instance, the length L1 can be defined as the Z-direction length of the region having a p-type impurity concentration of 1×10¹⁶ atoms/cm³ or more. The length L2 can be defined as the Z-direction length of the region having a p-type impurity concentration of 1×10¹⁶ atoms/cm³ or less.

The p-type semiconductor region 12 includes a third portion 123 and a fourth portion 124. The third portion 123 is provided between the second portion 112 and the n⁺-type source region 14 in the Z-direction. The third portion 123 overlaps the gate electrode 20 via the gate insulating layer 21 in the X-direction. The fourth portion 124 is provided between the first portion 111 and the p⁻-type semiconductor region 13 in the Z-direction. The fourth portion 124 does not overlap the p⁻-type semiconductor region 13 in e.g. the X-direction.

The p⁻-type semiconductor region 13 includes e.g. a fifth portion 135 and a sixth portion 136. The fifth portion 135 and the sixth portion 136 are provided between the second portions 112 in the X-direction. The sixth portion 136 is provided between the first portion 111 and the fifth portion 135 in the Z-direction.

The X-direction length L3 of the fifth portion 135 is longer than e.g. the thickness T1 of the p-type semiconductor region 12. On the other hand, the X-direction length L4 of the sixth portion 136 is shorter than e.g. the thickness T1. The thickness T1 is e.g. the thickness of the p-type semiconductor region 12 in the direction perpendicular to the interface between the n⁻-type semiconductor region 11 and the p-type semiconductor region 12. In an example, the thickness T1 is equal to the length L1.

The distance D1 between the second portions 112 and the thickness T1 satisfy e.g. the relation 0.01≦T1/D1≦0.5. In a different expression, the distance D1 is the X-direction distance between one second portion 112 and another second portion 112 nearest to the one second portion 112.

Next, an example method for manufacturing the semiconductor device 100 according to the first embodiment is described.

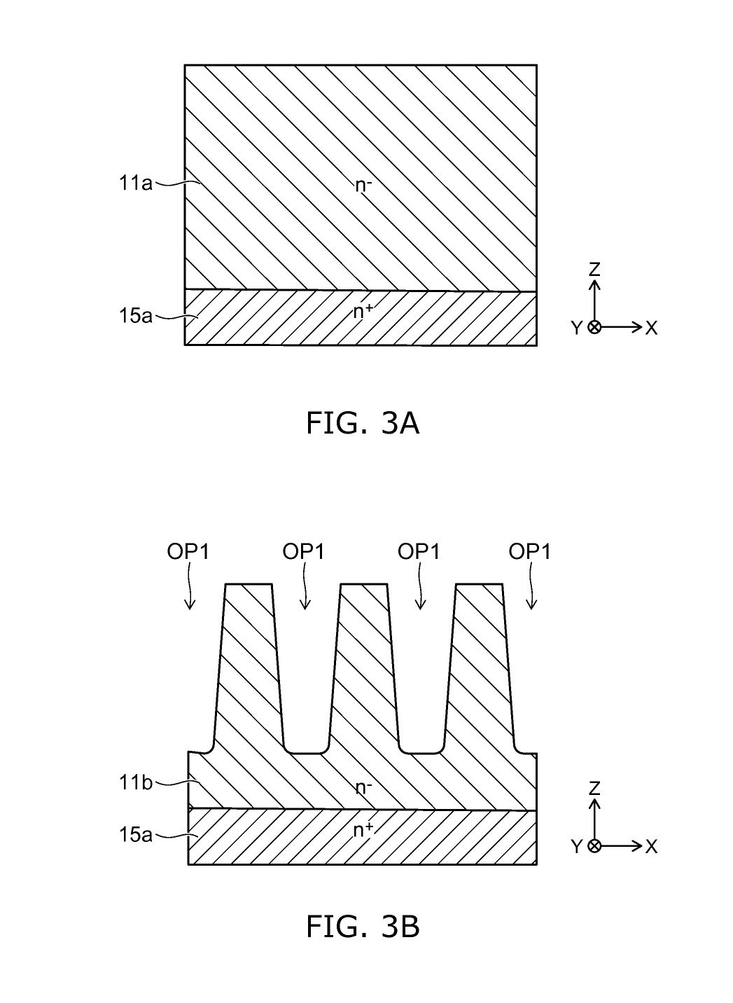

FIGS. 3A to 8B are process sectional views showing a process for manufacturing the semiconductor device 100 according to the first embodiment.

First, an n⁺-type semiconductor substrate (hereinafter referred to as substrate) 15a is prepared. The substrate 15a is composed primarily of e.g. silicon (Si). The substrate 15a may be composed primarily of gallium arsenide, silicon carbide, or gallium nitride. The substrate 15a contains an n-type impurity. The n-type impurity can be e.g. arsenic or phosphorus.

Next, as shown in FIG. 3A, Si is epitaxially grown on the substrate 15a while passing a gas containing an n-type impurity. Thus, an n⁻-type semiconductor layer 11a is formed. The gas containing an n-type impurity can be e.g. arsine (AsH₃), arsenic trifluoride (AsF₃), arsenic pentafluoride (AsF₅), arsenic trichloride (AsCl₃), arsenic pentachloride (AsCl₅), phosphine (PH₃), phosphorus trifluoride (PF₃), phosphorus pentafluoride (PF₅), phosphorus trichloride (PCl₃), phosphorus pentachloride (PCl₃), or phosphorus oxychloride (POCl₃).

Next, as shown in FIG. 3B, an opening OP1 is formed in the n⁻-type semiconductor layer 11a. The opening OP1 is provided in a plurality in the X-direction. Each opening OP1 extends in the Y-direction. The opening OP1 is formed by e.g. photolithography technique and RIE (reactive ion etching) technique. After forming the openings OP1, the damage layer formed on the inner wall of the opening OP1 by RIE may be removed by wet etching or CDE (chemical dry etching).

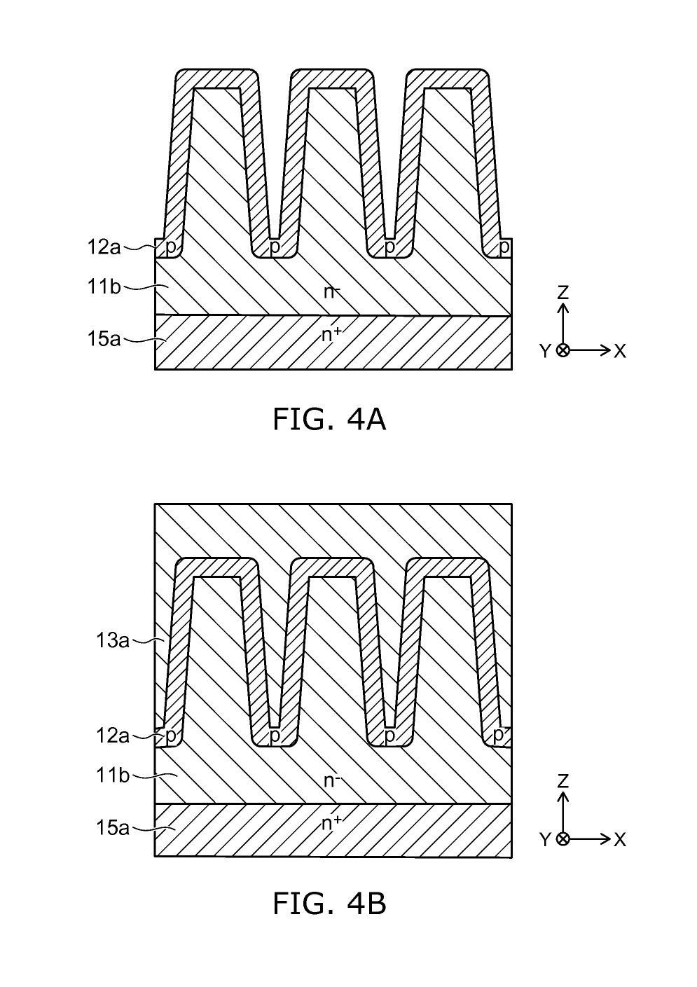

Next, as shown in FIG. 4A, Si is epitaxially grown on the n⁻-type semiconductor layer 11a while passing a gas containing a p-type impurity. A p-type semiconductor layer 12a is formed along the upper surface of the n⁻-type semiconductor layer 11a and the inner wall of the opening OP1.

The p-type impurity can be e.g. boron. The gas containing a p-type impurity can be e.g. diborane (B₂H₆), boron trifluoride (BF₃), boron trichloride (BCl₃), or boron tribromide (BBr₃).

Next, Si is epitaxially grown on the p-type semiconductor layer 12a while adding a p-type impurity. Thus, a semiconductor layer 13a is formed. At this time, the opening OP1 is filled with the semiconductor layer 13a. The amount of p-type impurity added when forming the semiconductor layer 13a is smaller than the amount of p-type impurity added when forming the p-type semiconductor layer 12a. That is, the p-type impurity concentration of the semiconductor layer 13a is lower than the p-type impurity concentration of the p-type semiconductor layer 12a. The n⁻-type semiconductor layer 11a, the p-type semiconductor layer 12a, and the semiconductor layer 13a constitute the semiconductor layer S shown in FIG. 1.

The semiconductor layer 13a may be formed without adding a p-type impurity. That is, a non-doped semiconductor layer 13a may be formed on the p-type semiconductor region 12. The term “non-doped” means that the semiconductor layer is not intentionally doped with impurity. FIG. 4B shows an example of forming a non-doped semiconductor layer 13a on the p-type semiconductor layer 12a. After forming the semiconductor layer 13a, the surface of the semiconductor layer 13a may be polished by e.g. CMP (chemical mechanical polishing) technique. The thickness of the semiconductor layer 13a is reduced by polishing. This can adjust the thickness of the p-type base region.

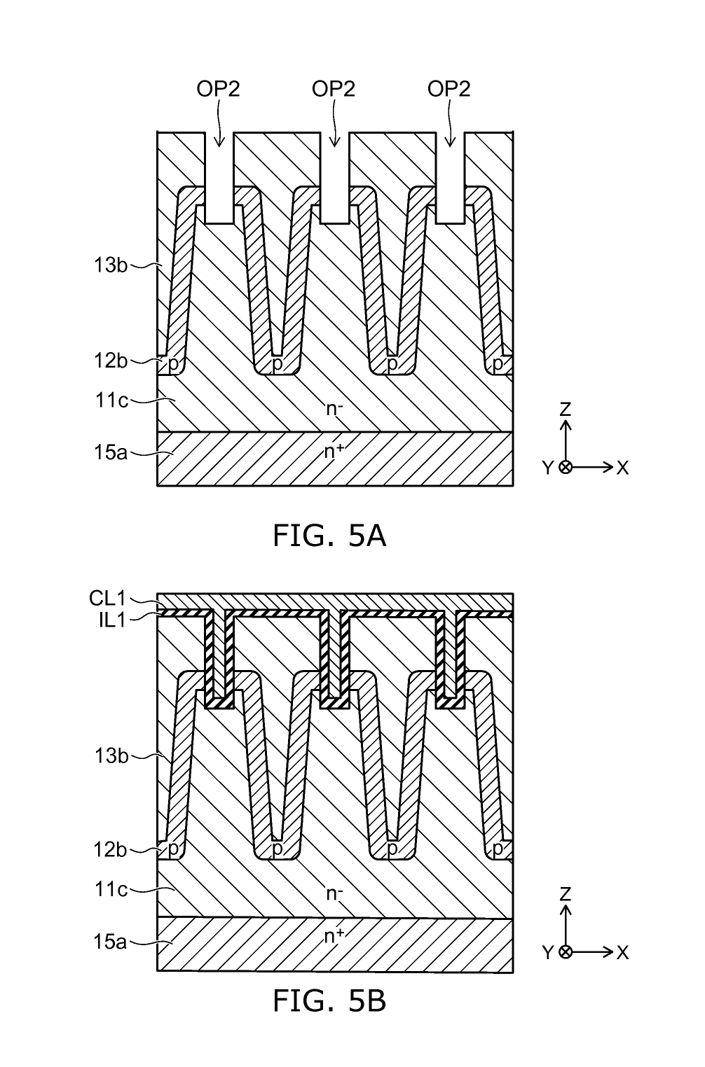

Next, as shown in FIG. 5A, an opening OP2 penetrating through the semiconductor layer 13a and the p-type semiconductor layer 12a to the n⁻-type semiconductor layer 11b is formed. The opening OP2 is formed by e.g. photolithography technique and RIE technique. After forming the opening OP2, the damage layer formed on the inner wall of the opening OP2 may be removed by e.g. wet etching or CDE.

This step removes part of the semiconductor layer 13a, part of the p-type semiconductor layer 12a, and part of the n⁻-type semiconductor layer 11b to form a semiconductor layer 13b, a p-type semiconductor layer 12b, and an n⁻-type semiconductor layer 11c. Simultaneously, part of the p-type semiconductor layer 12b and part of the n⁻-type semiconductor layer 11c are exposed through the opening OP2.

Next, an insulating layer IL1 is formed on the upper surface of the semiconductor layer 13a and the inner wall of the opening OP2. The insulating layer IL1 is formed by oxidizing the surface of the semiconductor layer 13a, the exposed portion of the p-type semiconductor layer 12a, and the exposed portion of the n⁻-type semiconductor layer 11b using e.g. thermal oxidation technique.

Next, as shown in FIG. 5B, a conductive layer CL1 is formed on the insulating layer IL1. The conductive layer CL1 is formed by using e.g. CVD (chemical vapor deposition) technique. The conductive layer CL1 includes e.g. polysilicon.

Next, part of the conductive layer CL1 formed on the upper surface of the semiconductor layer 13b is removed. This step sets back the upper surface of the conductive layer CL1 and divides the conductive layer CL1 into a plurality. As a result, the gate electrode 20 shown in FIGS. 1 and 2 is formed. After this step, the upper surface of the gate electrode 20 may be thermally oxidized to form an insulating layer.

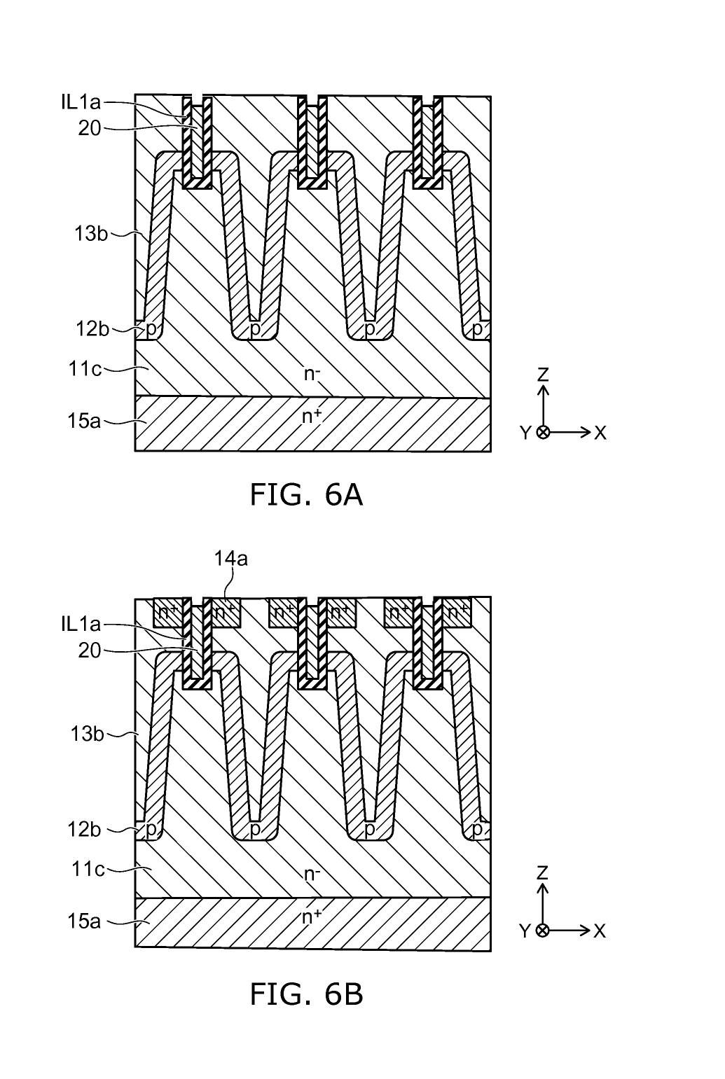

Next, as shown in FIG. 6A, part of the insulating layer IL1 is removed to expose at least part of the upper surface of the semiconductor layer 13a. This step divides the insulating layer IL1 into a plurality of insulating layers IL1a.

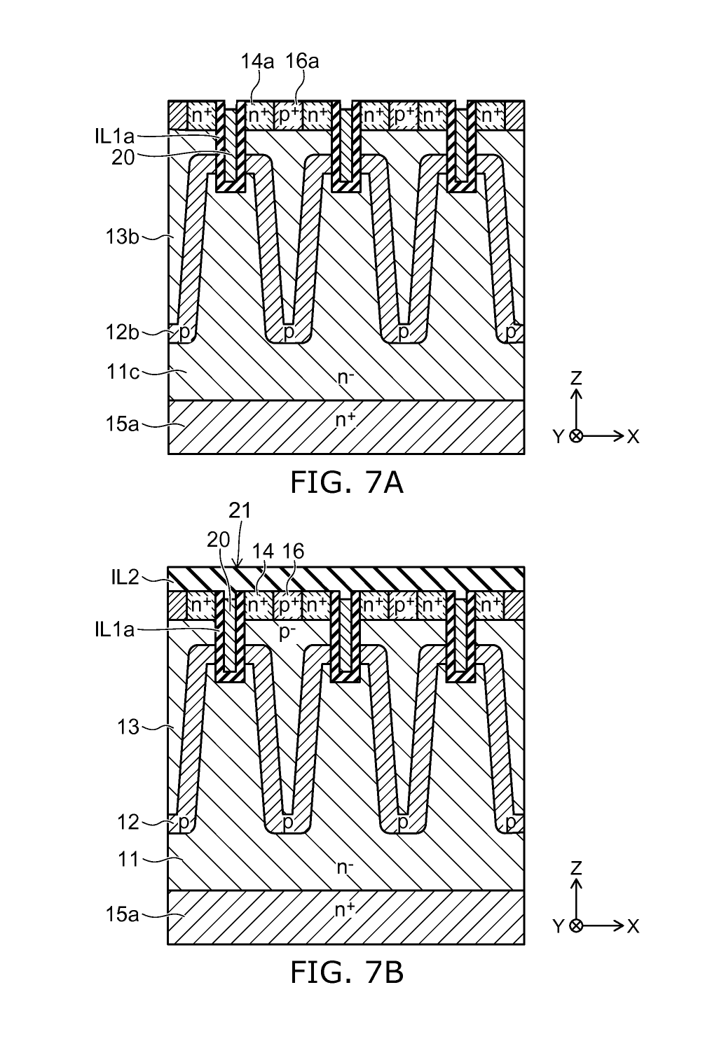

Next, as shown in FIG. 6B, an n-type impurity is ion implanted into part of the semiconductor layer 13a using a mask, not shown. Thus, an n⁺-type semiconductor region 14a is formed. Next, as shown in FIG. 7A, a p-type impurity is ion implanted into another part of the semiconductor layer 13a using a mask, not shown. Thus, a p⁺-type semiconductor region 16a is formed.

The n⁺-type semiconductor region 14a may be formed after the p⁺-type semiconductor region 16a is formed. Next, a heating treatment for activating the impurity contained in each semiconductor layer is performed. By the heating treatment, the p-type impurity is diffused from the p-type semiconductor layer 12a into the non-doped semiconductor layer 13a. Thus, a p⁻-type semiconductor region 13 is formed. This step forms the n⁻-type semiconductor region 11, the p-type semiconductor region 12, the p⁻-type semiconductor region 13, the n⁺-type source region 14, and the p⁺-type contact region 16 shown in FIGS. 1 and 2. The heating treatment for activation may be performed each time a semiconductor layer or semiconductor region is formed.

Next, as shown in FIG. 7B, an insulating layer IL2 covering the gate electrode 20, the n⁺-type source region 14, and the p⁺-type contact region 16 is formed. The insulating layer IL2 includes silicon oxide. The insulating layer IL2 is formed using CVD technique. Next, part of the insulating layer IL2 is removed to expose the n⁺-type source region 14 and the p⁺-type contact region 16. This step divides the insulating layer IL2 into a plurality. The divided insulating layer IL2 and the insulating layer IL1a constitute the gate insulating layer 21 shown in FIGS. 1 and 2.

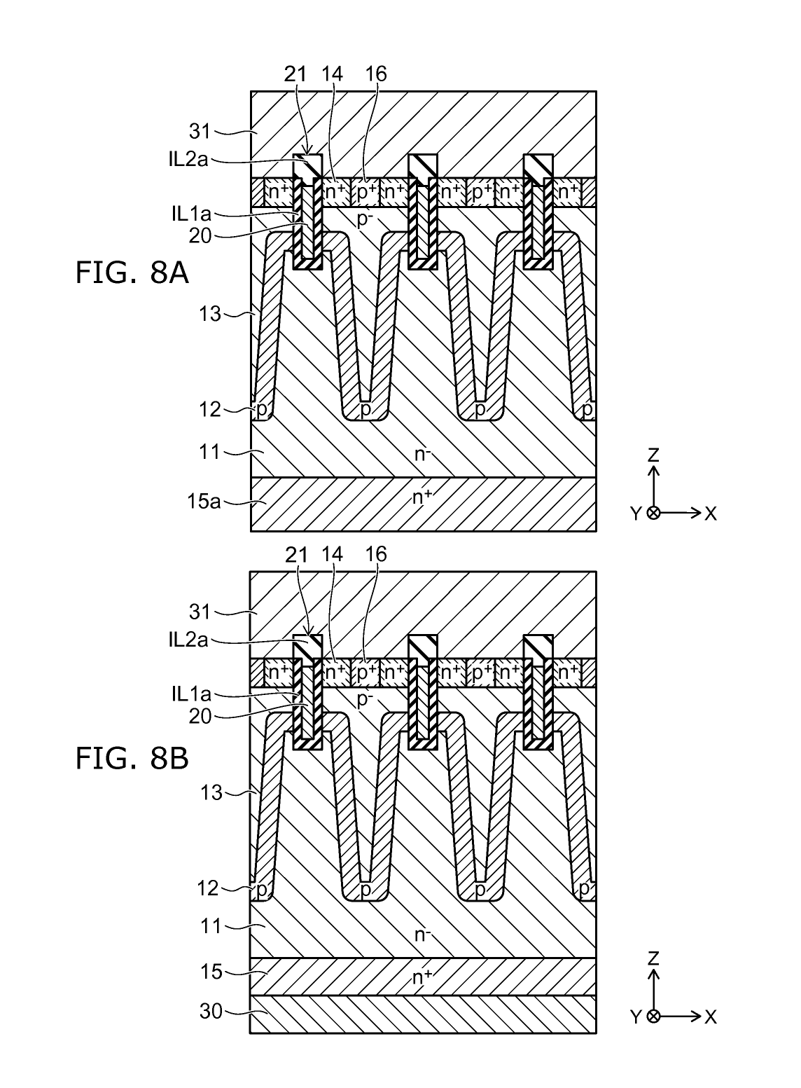

Next, as shown in FIG. 8A, a source electrode 31 is formed on the n⁺-type source region 14 and the p⁺-type contact region 16.

Next, the back surface of the substrate 15a is polished until the substrate 15a is reduced to a prescribed thickness. This step forms the n⁺-type drain region 15 shown in FIG. 1. Next, as shown in FIG. 8B, a drain electrode 30 is formed on the back surface of the substrate. Thus, the semiconductor device 100 is obtained.

Here, the operation and effect of the semiconductor device according to this embodiment are described.

First, a semiconductor device according to a comparative example is described. In the semiconductor device according to the comparative example, the p-type semiconductor region 12 is provided in the entire region between the second portions 112. The p⁻-type semiconductor region 13 is provided on the p-type semiconductor region 12. In this semiconductor device according to the comparative example, the n-type semiconductor region 11 and the p-type semiconductor region 12 form a super-junction structure.

The semiconductor device according to the comparative example incurs the decrease of breakdown voltage of the semiconductor device. Otherwise, the semiconductor device additionally requires an ion implantation step and a heating treatment step for forming a p-type base region constituting the MOSFET.

The reason for this is as follows.

It is desired that the total amount of p-type impurity contained in the p-type semiconductor region constituting the super-junction structure be nearly equal to the total amount of n-type impurity contained in the n-type semiconductor region constituting the super-junction structure. In the semiconductor device according to the comparative example, the p-type impurity concentration of the p-type semiconductor region 12 may be made equal to the p-type impurity concentration of the p-type base region constituting the MOSFET. Then, the total amount of p-type impurity contained in the p-type semiconductor region 12 may be excessive relative to the total amount of n-type impurity contained in the n-type semiconductor region 11. If the total amount of p-type impurity is excessive, the depletion layer does not sufficiently spread from the p-n junction interface between the n-type semiconductor region and the p-type semiconductor region constituting the super-junction structure. Thus, a sufficient breakdown voltage cannot be obtained.

On the other hand, the p-type impurity concentration of the p-type semiconductor region 12 may be matched with the n-type impurity concentration of the n⁻-type semiconductor region 11. Then, the p-type impurity concentration of the p-type semiconductor region formed between the n⁻-type semiconductor region 11 and the gate electrode 20 is made lower than the p-type impurity concentration necessary for the p-type base region of the MOSFET. This additionally requires an ion implantation step and a heating treatment step for forming a p-type base region after forming the p-type semiconductor region 12 and the p⁻-type semiconductor region 13.

In contrast, in the semiconductor device according to this embodiment, the p-type semiconductor region 12 is provided on the n⁻-type semiconductor region 11. The p⁻-type semiconductor region 13 is provided between the second portions 112 of the n⁻-type semiconductor region 11. The p-type impurity concentration of the p⁻-type semiconductor region 13 is lower than the p-type impurity concentration of the p-type semiconductor region 12. That is, in this embodiment, the second portion 112, part of the p-type semiconductor region 12, and part of the p⁻-type semiconductor region 13 form a super-junction structure. Furthermore, part of the p-type semiconductor region 12 also forms a base region in the MOSFET as well as forming the super-junction structure.

Use of such a configuration enables formation of a base region as well as formation of the p-type semiconductor region constituting the super-junction structure. Furthermore, this can also omit the ion implantation step and the heating treatment step for forming a base region. Thus, the productivity of the semiconductor device can be improved.

Furthermore, the omission of the heating treatment step for forming a base region suppresses diffusion of impurity from the n⁻-type semiconductor region 11 into the p-type semiconductor region 12 and diffusion of impurity from the p-type semiconductor region 12 into the n⁻-type semiconductor region 11. Thus, this embodiment can increase the n-type impurity concentration of the n⁻-type semiconductor region 11. Thus, the on-resistance of the semiconductor device can be reduced.

### Second Embodiment

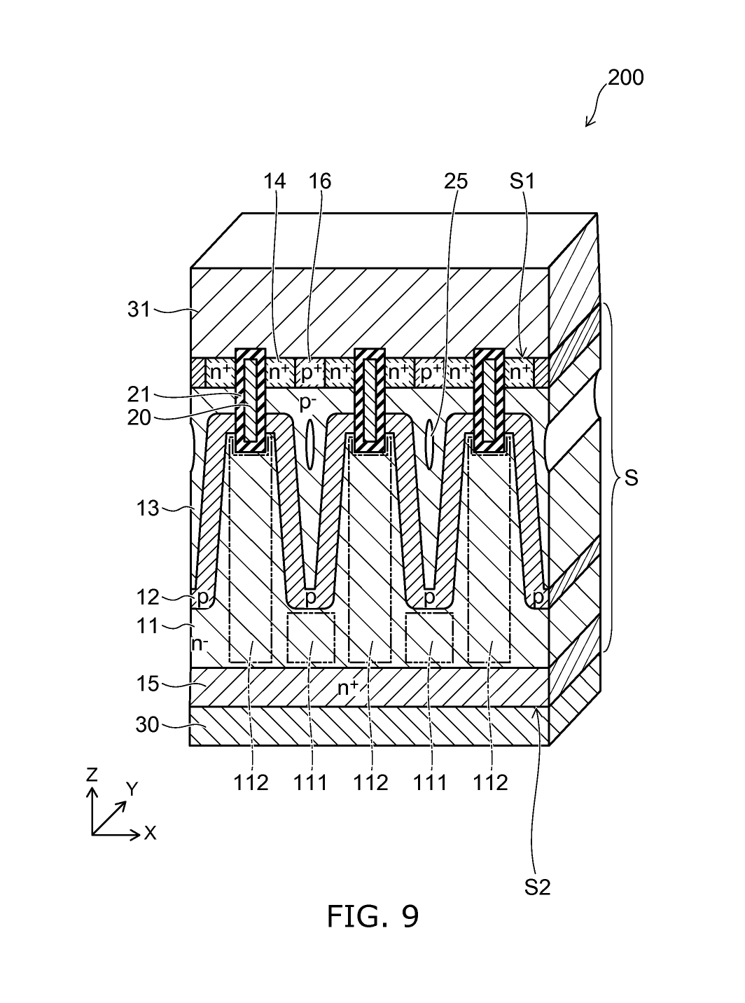

A semiconductor device 200 according to a second embodiment is described with reference to FIG. 9.

FIG. 9 is a perspective sectional view showing part of the semiconductor device 200 according to the second embodiment.

The semiconductor device 200 is different from the semiconductor device 100 in e.g. further including a void 25. The structure of the semiconductor device 200 other than the void 25 can be made similar to the structure of the semiconductor device 100.

The void 25 is surrounded with the p⁻-type semiconductor region 13. As an example, at least part of the void 25 is provided between the p-type semiconductor regions 12 in the X-direction and extends in the Y-direction. At least part of the void 25 is provided between the second portions 112 in e.g. the X-direction. The void 25 may be divided into a plurality in the Y-direction.

The void 25 overlaps e.g. the first portion 111 in the Z-direction via the p-type semiconductor region 12 and the p⁻-type semiconductor region 13. The void 25 overlaps e.g. the p⁺-type contact region 16 in the Z-direction via the p⁻-type semiconductor region 13.

Next, an example method for manufacturing the semiconductor device 200 is described.

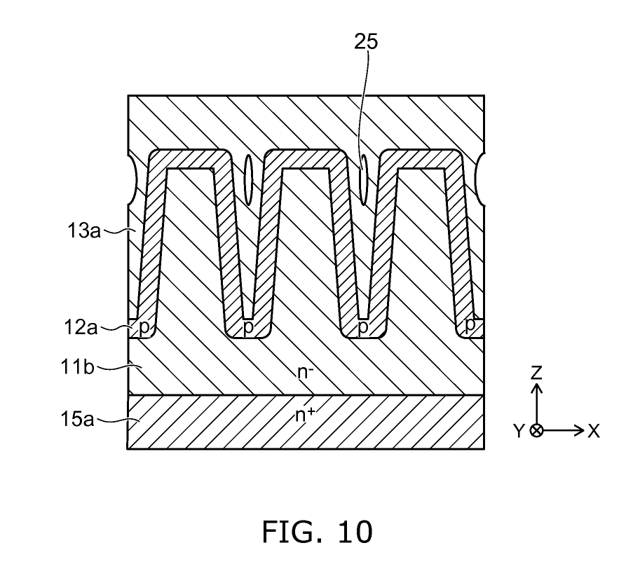

FIG. 10 is a process sectional view showing a process for manufacturing the semiconductor device 200.

First, steps similar to the steps shown in FIGS. 3A to 4A are performed to form a p-type semiconductor layer 12a on the n⁻-type semiconductor layer 11b. Next, a semiconductor layer 13a including a void 25 is formed on the p-type semiconductor layer 12a.

Then, steps similar to the steps shown in FIGS. 4B to 8B are performed. Thus, the semiconductor device 200 shown in FIG. 9 is obtained.

According to this embodiment, the semiconductor device 200 includes a void 25. Thus, the deposition amount of the semiconductor material necessary for forming the semiconductor layer 13a can be reduced when the semiconductor device 200 is fabricated.

At least part of the void 25 may be provided between the second portions 112 in the X-direction. In this case, the total amount of p-type impurity in the p-type semiconductor region forming the super-junction structure decreases with the volume of the void 25.

However, according to this embodiment, the void 25 is provided in the region surrounded with the p-type semiconductor region 12. The p-type impurity concentration of the p⁻-type semiconductor region 13 is lower than the p-type impurity concentration of the p-type semiconductor region 12. This can reduce the influence of the formation of the void 25 on the total amount of p-type impurity in the p-type semiconductor region forming the super-junction structure.

The relative magnitude of the impurity concentration between the semiconductor regions in the embodiments described above can be confirmed using e.g. SCM (scanning capacitance microscopy). The carrier concentration in each semiconductor region can be regarded as being equal to the concentration of impurity activated in the semiconductor region. Thus, the relative magnitude of the carrier concentration between the semiconductor regions can also be confirmed using SCM.

The impurity concentration in each semiconductor region can be measured by e.g. SIMS (secondary ion mass spectrometry).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a first semiconductor region of a first conductivity type including a plurality of first portions and a plurality of second portions, each of the first portions extending in a first direction, each of the second portions extending in the first direction, a length in a second direction of the second portion being longer than a length in the second direction of the first portion, the second direction being orthogonal to the first direction, and the plurality of first portions and the plurality of second portions being provided alternately in a third direction orthogonal to the first direction and the second direction;
a second semiconductor region of a second conductivity type provided on the first semiconductor region;
a third semiconductor region of the second conductivity type provided on the second semiconductor region, part of the third semiconductor region being located between the second portions, and impurity concentration of the second conductivity type of the third semiconductor region being lower than impurity concentration of the second conductivity type of the second semiconductor region;
a fourth semiconductor region of the first conductivity type selectively provided on the third semiconductor region;
a gate electrode provided on the second portion; and
a gate insulating layer provided between the gate electrode and each of the second portion, the second semiconductor region, the third semiconductor region, and the fourth semiconductor region.

2. The device according to claim 1, wherein part of the second semiconductor region and part of the third semiconductor region are provided between the first portion and the fourth semiconductor region in the first direction.

3. The device according to claim 1, wherein
the third semiconductor region includes a fifth portion and a sixth portion,
the fifth portion is provided between the second portions,
the sixth portion is provided between the first portion and the fifth portion,
a length in the second direction of the fifth portion is longer than thickness of the second semiconductor region, and
a length in the second direction of the sixth portion is shorter than the thickness of the second semiconductor region.

4. The device according to claim 1, further comprising:
a void surrounded with the third semiconductor region,
wherein at least part of the void is located between the second portions in the third direction.

5. A method for manufacturing a semiconductor device, comprising:
forming a first opening in a first semiconductor layer of a first conductivity type;
forming a second semiconductor layer of a second conductivity type along a surface of the first semiconductor layer;
forming a third semiconductor layer filling the first opening on the second semiconductor layer, impurity concentration of the second conductivity type of the third semiconductor layer being lower than impurity concentration of the second conductivity type of the second semiconductor layer;
forming a second opening penetrating through the second semiconductor layer and the third semiconductor layer to a region of the first semiconductor layer other than a region in which the first opening is formed;
forming an insulating layer along an inner wall of the second opening;
forming a conductive layer on the insulating layer; and
forming a first semiconductor region of the first conductivity type in part of a surface of the third semiconductor layer.

6. The method according to claim 5, wherein
in the forming the first opening, the first opening is formed in a plurality, the plurality of first openings are arranged in a first direction, and each of the first openings extends in a second direction orthogonal to the first direction,
the third semiconductor layer fills the plurality of first openings,
in the forming the second opening, the second opening is formed in a plurality, the plurality of second openings are arranged in the first direction, and each of the second openings extends in the second direction, and
the insulating layer lies along an inner wall of the plurality of second openings.

7. The method according to claim 6, wherein in the forming the conductive layer, the conductive layer fills the plurality of second openings.

8. The method according to claim 7, further comprising:
removing part of the conductive layer to divide the conductive layer into a plurality and to provide the respective conductive layers inside the respective second openings.

9. The method according to claim 8, wherein in the forming the first semiconductor region, the first semiconductor region is formed in a plurality, and at least part of each of the first semiconductor regions is located between the conductive layers.

10. The method according to claim 5, wherein in the forming the first semiconductor region, the first semiconductor region is formed so that part of the second semiconductor layer of the second conductivity type remains between the first semiconductor region and the first semiconductor layer.

11. The method according to claim 5, wherein the third semiconductor layer includes a void.
